(19) United States
(12) Patent Application Publication
(10) Pub. No.: US 2011/0146909 A1
(43) Pub. Date: Jun. 23, 2011

(54) METHODS FOR WET CLEANING QUARTZ SURFACES OF COMPONENTS FOR PLASMA PROCESSING CHAMBERS

(75) Inventors: Hong Shih, Walnut, CA (US); Tuochuan Huang, Saratoga, CA (US); Duane Outka, Fremont, CA (US); Jack Kuo, Pleasanton, CA (US); Shenjian Liu, Fremont, CA (US); Bruno Morel, Santa Clara, CA (US); Anthony Chen, Pleasanton, CA (US)

(73) Assignee: Lam Research Corporation, Fremont, CA (US)

(21) Appl. No.: 13/016,561

(22) Filed: Jan. 28, 2011

Related U.S. Application Data
(63) Continuation of application No. 10/863,360, filed on Jun. 9, 2004, now abandoned.

(51) Int. Cl. C01B 33/12; B08B 3/00; H01L 21/3065

(52) U.S. Cl. 156/345.35; 134/27; 156/345.1; 423/335

(57) ABSTRACT

Methods for wet cleaning quartz surfaces of components for plasma processing chambers in which semiconductor substrates are processed, such as etch chambers and resist stripping chambers, include contacting the quartz surface with at least one organic solvent, a basic solution and different acid solutions, so as to remove organic and metallic contaminants from the quartz surface. The quartz surface is preferably contacted with one of the acid solutions at least two times.

### BACKGROUND

Semiconductor substrate materials, such as silicon wafers, are processed in plasma processing chambers by techniques including deposition, dry etching and resist stripping processes. Surfaces of components of such chambers are exposed to and continuously attacked by the plasma and corrosive gases. Due to this exposure, these components are eroded and accumulate by-product buildup, necessitating replacement or thorough cleaning. Eventually, components wear out and become unusable in the chamber. These components are referred to as “consumables.” Therefore, if the part's lifetime is short, then the cost of the consumable is high (i.e., part cost/part lifetime).

### SUMMARY

Methods for wet cleaning quartz surfaces of components for plasma processing chambers in which semiconductor substrates are processed are provided. A preferred embodiment comprises a) contacting at least one quartz surface of a component with at least one organic solvent effective to degrease and remove organic contaminants from the quartz surface; b) after a), contacting the quartz surface with a weak basic solution effective to remove organic and metallic contaminants from the quartz surface; c) after b), contacting the quartz surface with a first acid solution effective to remove metallic contaminants from the quartz surface; d) after c), contacting the quartz surface with a second acid solution comprising hydrofluoric acid and nitric acid to remove metallic contaminants from the quartz surface; and e) optionally repeating d) at least once.

A preferred embodiment of a component for a plasma processing chamber in which semiconductor substrates are processed comprises at least one quartz surface on which the amounts of Al, Ca, Cr, Cu, Fe, Li, Mg, Ni, K, Na, Ti, Zn, Co and Mo are (×10¹⁰ atoms/cm²): Al≦300; Ca≦95; Cr≦50; Cu≦50; Fe≦65; Li≦50; Mg≦50; Ni≦50; K≦100; Na≦100; Ti≦60, Zn≦50, Co≦30 and Mo≦30.

A preferred embodiment of a resist stripping apparatus is provided, which comprises a resist stripping chamber; a remote plasma source operable to generate a plasma and introduce reactive species into the resist stripping chamber; and a baffle including at least one quartz surface that has been wet cleaned.

A preferred embodiment of a plasma processing chamber is provided, which comprises at least one component including at least one quartz surface that has been cleaned, wherein the quartz surface is exposed to plasma and/or process gases in the plasma processing chamber.

A preferred embodiment of a method of processing a semiconductor substrate in a plasma processing chamber comprises cleaning at least one quartz surface of at least one component, placing the as-cleaned component in the plasma processing chamber such that the component is exposed to plasma and/or process gas, the plasma processing chamber containing a semiconductor substrate; and energizing a process gas into the plasma state remote from or inside the plasma processing chamber to process the substrate.

### BRIEF DESCRIPTION OF THE DRAWINGS

FIG. 1 depicts an exemplary embodiment of a resist stripping chamber including a quartz baffle.

FIG. 2 depicts an embodiment of a substrate including a resist that can be processed in the resist stripping chamber shown in FIG. 1.

FIG. 3 depicts a plasma processing chamber including components including one or more quartz surfaces.

### DETAILED DESCRIPTION

In plasma processing operations, semiconductor substrates, such as silicon wafers, are subjected to plasma etching processes to remove material from the substrates, and/or to deposition processes, such as chemical vapor deposition (CVD) and plasma-enhanced chemical vapor deposition (PECVD) processes, to deposit material on the substrates. Etching processes remove metallic, semiconductor and/or insulator materials, for example, dielectric materials, from the substrates. Deposition processes can deposit, for example, various metals, such as aluminum, molybdenum and tungsten, and dielectric materials, such as silicon dioxide and silicon nitride on substrates.

Resist stripping chambers are used in semiconductor device manufacturing processes to remove protective masks, such as resist materials, e.g., organic photoresist, from semiconductor substrates. Dry stripping, also referred to as “ashing,” is a plasma etching technique that is performed in resist stripping chambers to remove resist from semiconductor structures.

It has been determined that plasma etching, deposition and/or resist stripping processes result in the accumulation, in the plasma chamber, of inorganic and organic contaminants on quartz (SiO₂) surfaces of components, i.e., on surfaces of components made of quartz (e.g., monolithic components) or on quartz surfaces of components that comprise quartz in addition to at least one other material, for example, components that include a quartz coating formed as an outer layer on an underlying substrate. As used herein, the term “outer surface” means the entire outer surface of a component, which may include one or more quartz surfaces. The outer surface may include at least one surface that is not of quartz, for example, a non-coated surface.

Components for plasma processing apparatuses that have quartz surfaces include, for example, dielectric windows, process gas injectors and/or injection rings, view ports, plasma confinement rings, focus rings and edge rings surrounding a substrate on a substrate support, and gas distribution plates and baffles for distributing process gases. The components can have various shapes including plate shapes, ring shapes, disk shapes, cylindrical shapes and combinations of these shapes and other shapes.

During plasma etching, deposition and resist stripping processes, etch byproducts, deposition materials, stripping byproducts and other materials can deposit on quartz surfaces of components in plasma chambers. In resist stripping chambers, strip by-products including organic and inorganic contaminants can accumulate on the bottom surface of gas distribution plates and baffles and cause a reduction in the strip rate. While not wishing to be limited to any particular theory, the mechanism for strip rate reduction is believed to be the loss of downstream atomic oxygen flux caused by the increased occurrence of surface recombination on, for example, deposits of AlₓO_{y} and TiO_{y}, as compared with the recombination that occurs on a clean SiO₂ surface.

In light of the above-described problems associated with the contamination of quartz surfaces of components for plasma processing apparatuses, methods of cleaning such quartz surfaces are provided. The quartz surfaces are preferably surfaces that are exposed to plasma and/or corrosive process gases in a plasma processing chamber. Preferred embodiments of the methods can be practiced to clean components made of quartz (e.g., monolithic components) and components having one or more quartz surfaces, for example, quartz-coated components. The methods can recondition used parts by removing organic and inorganic contaminants from quartz surfaces of components that have been exposed to plasma in plasma processing chambers, i.e., used components, to achieve desirably low levels of at least selected metallic contaminants on the quartz surfaces.

A preferred embodiment of the methods of cleaning quartz surfaces of components for plasma processing apparatuses includes an optional first step, which is a pre-cleaning, or “rough cleaning” procedure. The pre-cleaning procedure is preferably performed when the quartz surface of a component is determined to be highly contaminated, for example, the contamination level on the quartz surface is sufficiently severe to be visible to the eye. The pre-cleaning procedure includes blasting the outer surface of the component using a high-pressure (for example, about 20 psi to about 80 psi) spray of deionized (DI) water. The outer surface is sprayed until loose surface deposition is removed, e.g., spraying for from about 5 minutes to about 15 minutes. After cleaning the outer surface with water, the component is dried. The drying step preferably uses clean, dry air or the like.

In the embodiment, one or more quartz surfaces of the component can be masked to prevent contact with the cleaning chemicals. For example, for a quartz window, the sealing surface can be masked using a “TEFLON” fixture or a quartz ring, or with a contaminant-free tape or the like. Visible deposition is preferably removed from the non-masked portion of the outer surface of the component using filtered, pressurized CO₂ or the like.

In the embodiment, the outer surface of the component is then rinsed with DI water for a suitable time, such as from about 5 minutes to about 15 minutes, to remove loose particles from the outer surface, so as to complete the first step.

The component is then ready to be cleaned using the enhanced wet cleaning procedure described below. In the embodiment, the enhanced wet cleaning procedure preferably includes three steps, i.e., steps two to four of the method. In the embodiment, the second step preferably degreases the quartz surface(s) of the component to remove organic contaminants, such as finger oils, grease, particles and organic compounds. Organic contaminants can deposit on quartz surfaces during various plasma processes, including metal etch processes that use CHF₃, CF₄ and like process gases, or during resist stripping processes that use CF₄, C₂F₆ or the like. In the embodiment, the third step is performed to remove organic contaminants remaining on the quartz surface of the component after the first step and to remove inorganic contaminants. In the embodiment, the fourth step is a final cleaning and packaging procedure.

In the embodiment, the second step includes initially rinsing the component using DI water to remove loose particles from the quartz surface, typically for from about 5 minutes to about 15 minutes, followed by drying the component.

In the embodiment, the second step includes then contacting the outer surface with a suitable first solvent. As used herein, the term “contacting” means applying a liquid to the outer surface of a component by any suitable technique which is effective to remove undesired substances present on the outer surface. For example, the component to be cleaned can be dipped or immersed in the liquid, or sprayed or splashed with the liquid. The first solvent is an organic solvent, preferably isopropyl alcohol. The component is preferably immersed in the first solvent at a temperature of about 20° C. to about 25° C. for from about 15 minutes to about 30 minutes, and then wiped with a non-contaminating wipe until no visible residue is removed from the quartz surface(s) on the wipe. The component is then rinsed using DI water to remove residual first solvent and loose surface particles, typically for from about 5 minutes to about 15 minutes, after which the component is dried, such as with nitrogen.

In the embodiment, the second step includes then contacting the component with a suitable second solvent. The second solvent is an organic solvent, preferably acetone. The component is preferably immersed in the second solvent at a temperature of about 20° C. to about 25° C. for from about 15 minutes to about 30 minutes, and then wiped with a non-contaminating wipe until no visible residue is removed from the quartz surface(s) on the wipe. Acetone is effective to remove organic contaminants from the quartz surface(s) of the component. The component is preferably then rinsed using DI water to remove residual solvent and loose surface particles from the outer surface, typically for about 5 to about 15 minutes, after which the component is dried, such as with nitrogen.

In the embodiment, the second step preferably includes then ultrasonically cleaning the component in ultra-pure water (preferably having a resistivity of at least about 15 Mohm-cm at about ambient temperature) for from about 20 minutes to about 40 minutes, followed by drying the component with a suitable gas, such as filtered nitrogen.

In the embodiment, the third step preferably removes organic contaminants remaining on the quartz surface(s) of the component after completion of the second step, as well as inorganic contaminants, including, but not limited to, Si, Ca, Mg, Fe, Co, Co, Na, K, Al, Ti, Zn, Li, Ni, Cr, Mo, TiF₄, AlF₃, AlOₓF_{y} and Al₂O₃.

In the embodiment, the third step preferably includes initially treating the component with a mixed, weak basic solution that is effective to remove metallic and organic contaminants from the quartz surface(s) of the components. The basic solution preferably contains ammonium hydroxide (NH₄OH) and hydrogen peroxide (H₂O₂). Ammonium hydroxide forms complex ions with heavy metals, such as Ni, Cr, Co and Cu. Hydrogen peroxide is a strong oxidizer and is effective to break organic bonds and react with metals and metal ions. The basic solution can have a volume ratio of NH₄OH:H₂O₂ (preferably 30%):H₂O of, for example, about 1:1:2-8 or 1:x:8 (where x=2-7), preferably about 1:1:2. Preferably, the component is immersed in the basic solution at a temperature of from about 20° C. to about 25° C. for about 20 minutes to about 30 minutes. Then, the component is rinsed with DI water to remove residual solution and contaminants and then dried, such as with nitrogen.

In the embodiment, the third step includes then treating the component with a first acid solution that is effective to remove heavy metals, such as Mo, Zn, Ti, Co, Ni, Cr, Fe and Cu, and preferably at least Ca, Mg, Na, K and Al from the quartz surface(s). The first acid solution preferably contains hydrochloric acid (HCl). An exemplary first acid solution that can be used is an aqueous 6 wt % HCl solution. Preferably, the component is immersed in the first acid solution at a temperature of from about 20° C. to about 25° C. for about 10 minutes to about 20 minutes. Then, the component is rinsed with DI water to remove residual first acid solution and contaminants, after which it is dried, such as with nitrogen.

In the embodiment, the third step preferably includes then treating the component with a second acid solution that is effective to remove Ca, Mg, Fe, Na, K and Al, as well as Si, Ti, Cu, Zn, Li, Ni, Cr and Mo from the quartz surface. The second acid treatment is performed at least once, e.g., twice and more preferably three times. The second acid solution preferably contains a mixture of hydrofluoric acid (HF) and nitric acid (HNO₃). The hydrofluoric acid dissolves silicon and SiO₂-based materials. The nitric acid dissolves metal ions, oxides and inorganic etch by-products from the quartz surface. The second acid solution preferably contains from about 1 wt % to about 5 wt % hydrofluoric acid and from about 5 wt % to about 20 wt % nitric acid, more preferably about 1 wt % hydrofluoric acid and about 10 wt % nitric acid, and water.

The component is preferably immersed in the second acid solution at a temperature of from about 20° C. to about 25° C. for a period of from about 10 minutes to about 20 minutes. After each immersion in the second acid solution, the component is rinsed with DI water to remove residual second acid solution and surface particles and is then dried, such as with nitrogen. The second acid cleaning procedure is repeated at least once, preferably twice.

Hydrofluoric acid can aggressively remove silicon from the quartz components at a rate of about 2300 angstroms/day or even higher. For this reason, the total amount of time that the quartz component is contacted with the second acid solution is preferably a maximum of from about 30 to about 60 minutes, more preferably a maximum of about 30 minutes. For each second acid treatment, the quartz component is preferably contacted with the second acid solution for no more than about 20 minutes. It has been determined that when the quartz component is maintained in the second acid solution for longer than about 20 minutes, the solution tends to reach an equilibrium state in which further metal removal from the component stops, although the second acid solution continues to dissolve silicon from the component. As a result, an undesirably high amount of silicon removal occurs. By performing the second acid cleaning for no more than about 20 minutes for each respective second acid treatment, the total amount of silicon that is removed from the component surface by the solution is acceptably low, while organic and metallic contaminants are effectively removed from the quartz surface(s).

In the embodiment, the fourth step is performed after completion of the third step to finish cleaning the component. The fourth step is preferably performed in a class 100 clean room, more preferably in a class 10 clean room. Clean rooms having these designations can respectively contain up to 100 particles and up to 10 particles having a size of 0.5 microns, per cubic foot. The fourth step preferably includes first fully immersing the component into ultra-pure DI water in a tank for from about 10 minutes to about 20 minutes. Then, the component is preferably subjected to an ultrasonic treatment, preferably in ultra-pure water, for from about 40 minutes to about 80 minutes. Then, the component is preferably fully immersed into ultra-pure DI water for from about 10 to about 20 minutes. The component is then dried preferably by heating at a temperature of about 110° C. to 130° C. for a sufficient amount of time to dry the component. Depending on the size of the component, the drying time can vary. For example, the drying time is typically about two hours for a large component, for example, a large dielectric window or gas distribution plate or baffle, and about one hour for smaller components, such as focus rings or edge rings. After drying, the component is preferably double packaged with class 100 packing bags.

The methods of cleaning quartz surfaces of components of plasma processing apparatuses can preferably achieve the following amounts of metallic contaminants (×10¹⁰ atoms/cm²) on the as-cleaned quartz surfaces: Al≦300, Ca≦95, Cr≦50, Cu≦50, Fe≦65, Li≦50, Mg≦50, Ni≦50, K≦100, Na≦100, Ti≦60, Zn≦50, Co≦30 and Mo≦30. These metals are undesirable contaminants of semiconductor devices. The surface metal levels can be determined using an inductively-coupled plasma/mass spectrometer (ICP-MS). It has been determined that by cleaning the quartz surfaces to achieve such low metallic contamination levels, particle problems caused by the generation of particles of these contaminants can be avoided. Preferably, the cleaning methods do not detrimentally affect the surface finishes of quartz surfaces of components.

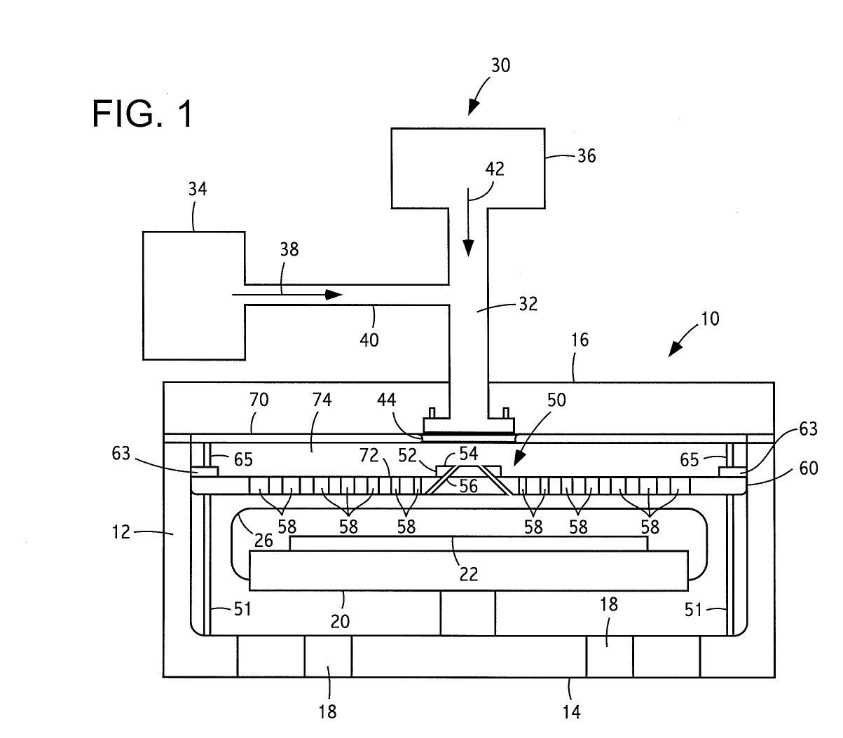

As mentioned above, the as-cleaned components can be installed in various plasma processing apparatuses. For example, FIG. 1 depicts an embodiment of a resist stripping chamber 10 in which a preferred embodiment of quartz baffle 50 is mounted. The resist stripping chamber 10 includes a side wall 12, a bottom wall 14 and a cover 16. The walls 12, 14 and the cover 16 can be of any suitable material, such as anodized aluminum. The cover 16 can be opened to remove the quartz baffle 50 for cleaning, or for other purposes. The resist stripping chamber 10 includes vacuum ports 18 in the bottom wall 14.

The resist stripping chamber 10 also includes a substrate support 20 on which a semiconductor substrate 22, such as a silicon wafer, is mounted during resist stripping. The substrate 22 includes a resist that provides a masking layer for protecting underlying layers of the substrate 22 during an earlier etching process. The underlying layers can be of an electrical conductor, insulator and/or semiconductor material. The substrate support 20 preferably comprises an electrostatic chuck adapted to clamp the substrate 22. The substrate support 20 preferably also includes a heater adapted to maintain the substrate 22 at a suitable temperature during the resist stripping process, preferably from about 200° C. to about 300° C., more preferably from about 250° C. to about 300° C. The substrate 22 can be introduced into, and removed from, the resist stripping chamber 10 through a substrate entry port 26 provided in the sidewall 12. For example, the substrate 22 can be transferred under vacuum into the interior of the resist stripping chamber 10 from an etching chamber located proximate the resist stripping chamber.

In the embodiment, a remote plasma source 30 is in fluid communication with the resist stripping chamber 10. The plasma source 30 is operable to produce plasma and to supply reactive species into the interior of the resist stripping chamber 10 through a passage 32 connected to the resist stripping chamber 10. The reactive species remove resist from the substrate 22 supported on the substrate support 20. The illustrated embodiment of the plasma source 30 includes a remote energy source 34 and a stripping gas source 36. The energy source 34 is preferably a microwave generator. In a preferred embodiment, the microwave generator operates at a frequency of 2.45 GHz, and preferably has a power in the range of about 500 to about 1500 W, more preferably in the range of about 1000 to about 1500 W. Microwaves, represented by arrow 38, are produced by the microwave generator 34 and propagated through a waveguide 40 into the passage 32.

The gas source 36 is adapted to supply process gas, such as oxygen, represented by arrow 42, into the passage 32, where the gas is energized into the plasma state by the microwaves 38. Reactive species pass through an opening 44 into the interior of the resist stripping chamber 10.

The reactive species are distributed in the resist stripping chamber 10 by a quartz baffle 50 located between the cover 16 and the substrate support 20 before the reactive species flow onto the substrate 22 and strip the resist. The substrate 22 is preferably heated during resist stripping. Waste products generated during resist stripping are pumped out of the resist stripping chamber 10 through the exhaust ports 18.

The quartz baffle 50 is preferably a disc-shaped body of quartz. The resist stripping chamber 10 is preferably cylindrical for single wafer processing. When adapted to be installed in a cylindrical resist stripping chamber 10, the quartz baffle 50 has a diameter that is slightly less than the width, for example, diameter, of the interior of the resist stripping chamber 10. The baffle 50 is preferably supported by three or more supports 51 (two are shown) protruding from the bottom wall 14. The quartz baffle 50 includes an inner portion having a raised central portion 52 with an upper surface 54 and through passages 56. In the illustrated embodiment of the quartz baffle 50, the central portion 52 includes six circumferentially spaced-apart passages 56. The number of passages 56 can be either more or less than six in other embodiments. In the embodiment, the central portion 52 of the quartz baffle 50 is opaque. The passages 56 are preferably oriented at an acute angle relative to the upper surface 54 so that there is no direct line of sight for the UV radiation to pass through the quartz baffle 50 and damage the substrate 22.

The quartz baffle 50 also includes through passages 58 arranged between the central portion 52 and a peripheral portion 60. The passages 58 are adapted to distribute reactive species in a desired flow pattern into the interior of the resist stripping chamber 10. The passages 58 preferably are arranged in concentric rows of holes. The passages 58 preferably have a round cross section and preferably increase in cross-sectional size (for example, diameter) in the radial outward direction of the quartz baffle 50 from the central portion 52 toward the peripheral portion 60.

A liner 70 is adapted to be supported on the upper surface 72 of the quartz baffle 50 to minimize the deposition of materials on the bottom surface of the cover 16 during resist stripping processes. A ring 63 is provided on the upper surface 72. Circumferentially spaced-apart spacers 65 are provided on the ring 63 to support the liner 70 and form a plenum 74 therebetween (FIG. 1). The ring 63 can be of anodized aluminum, for example. The spacers 65 can be of any suitable material and are preferably of “TEFLON.” The liner 70 includes the centrally located passage 44 through which reactive species pass from the passage 32 into the plenum 74. The liner 70 can be of any suitable material, such as anodized aluminum.

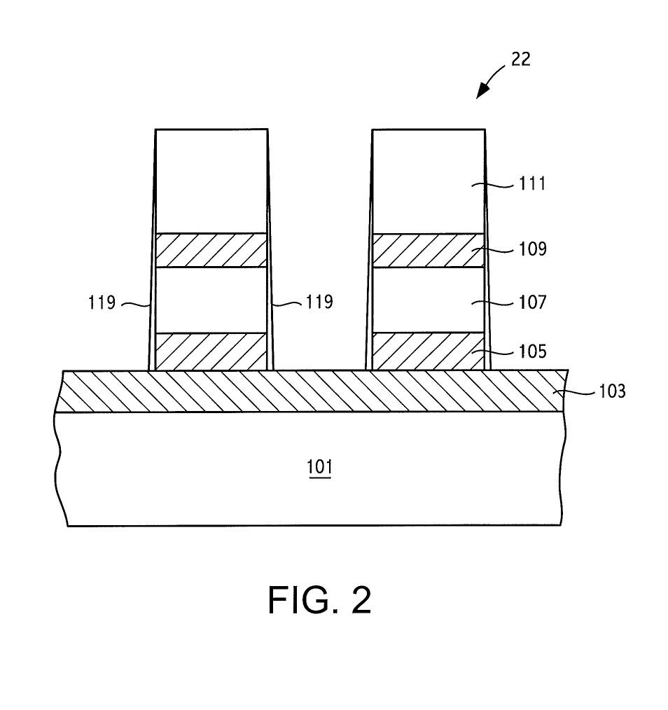

FIG. 2 shows an exemplary embodiment of the substrate 22. The substrate 22 includes a base substrate 101, typically of silicon; an oxide layer 103, such as SiO₂, formed on the substrate 101; and one or more barrier layers 105 of, for example, Ti, TiN, TiW or the like, formed between the oxide layer 103 and an overlying metal layer 107. The metal layer 107 can comprise, for example, tungsten, aluminum, or aluminum alloy, such as Al—Cu, Al—Si, or Al—Cu—Si. There is a hard mask opening in the metal etch stack. The hard mask can be of any suitable material, such as SiON, which can be etched using a gas mixture containing CHF₃ or CF₄. The substrate 22 can include an antireflective coating (ARC) layer 109 of any suitable material, such as TiN or TiW. A patterned resist layer 111 (e.g., organic photoresist) is formed over the ARC layer 109. Processing byproducts 119 are shown on the walls.

The process gas used to form the remote plasma includes oxygen, which is excited into a plasma state to produce oxygen radicals and ion species, which are flowed into the interior of the resist stripping chamber 10 and react with (i.e., oxidize or “ash”) the resist layer 111. The rate at which the resist is removed from the substrate 22 by the strip process is referred to as the “strip rate.”

The resist stripping process gas can have any suitable composition, such as an O₂/N₂, O₂/H₂O, O₂/N₂/CF₄ or O₂/N₂/H₂O gas mixture. The gas mixture preferably comprises O₂, N₂, and a fluorine-containing component, such as CF₄ or C₂F₆. N₂ can be added to the gas mixture to enhance selectivity with respect to the resist material as compared to a second material, such as a barrier and/or underlying material. Exemplary gas mixtures can contain, for example, by total gas volume, from about 40% to about 99%, preferably from about 60% to about 95%, and more preferably from about 70% to about 90% O₂; from about 0.5% to about 30%, preferably from about 2.5% to about 20%, and more preferably from about 5% to about 15% of fluorine-containing gas; and from about 0.5% to 30%, preferably about 2.5% to 20%, and more preferably about 5 to 15% of N₂. During stripping, depending on factors including the wafer size (200 mm or 300 mm) the total flow rate of the process gas is preferably in the range of from about 500 to about 6000 sccm, more preferably from about 2000 to about 5000 sccm, and the pressure in the resist stripping chamber 10 is preferably in the range of about 200 mTorr to about 10 Torr.

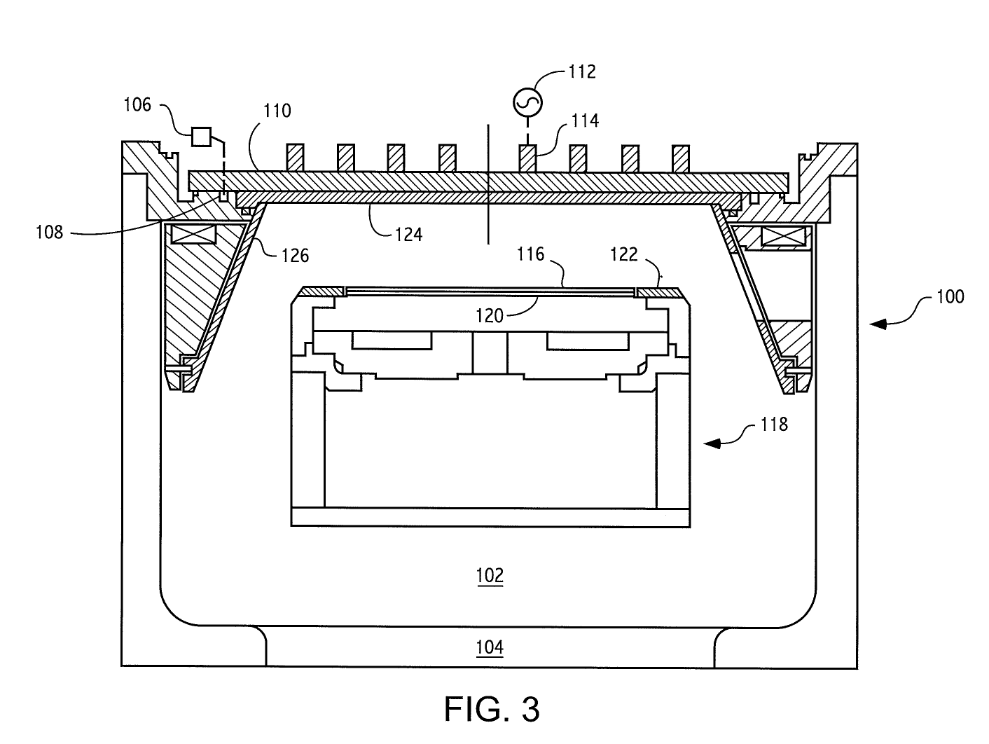

FIG. 3 illustrates a plasma processing chamber 100 that includes exemplary components that can have one or more quartz surfaces that can be cleaned by a preferred embodiment of the methods described herein. The plasma processing chamber 100 includes a substrate holder 118 with an electrostatic chuck 120 operable to provide a clamping force to a substrate 116. A focus ring 122 confines plasma above the substrate 116. The focus ring 122 can include one or more quartz surfaces, for example. A source of energy for maintaining plasma in the chamber, such as an antenna 114 powered by an RF source 112, is located above a dielectric window 110. The dielectric window 110 forms the top wall of the plasma processing chamber and can include one or more quartz surfaces. The plasma processing chamber 100 includes vacuum pumping apparatus for maintaining a desired vacuum pressure during plasma processing.

A gas distribution plate 124 is provided beneath the dielectric window 110 and includes gas passages through which process gas is delivered from a gas supply 106 to the interior of the plasma processing chamber 110. An optional liner 126 extends downwardly from the gas distribution plate 124 and surrounds the substrate holder 118. The liner 126 can include one more quartz surfaces.

In operation, substrate 16, such as a silicon wafer, is positioned on the substrate holder 118 and electrostatically clamped by electrostatic chuck 120. Process gas is supplied to the vacuum processing chamber 100 by passing the process gas through a gap between the dielectric window 110 and the gas distribution plate 124. The process gas is energized by the energy source 112, 114 to generate plasma in the interior of the plasma processing chamber 100.

The methods for cleaning quartz surfaces of components can be used to clean quartz components used in various plasma etch reactors adapted for etching silicon, conductors including, for example, metals and polysilicon, and dielectric materials from 200 and 300 mm wafers. Exemplary plasma etch reactors include the 2300 “EXELAN” and “EXELAN” HPT dielectric etch systems, the 2300 “VERSYS” conductor etch system, the 2300 “VERSYS STAR” silicon etch system, and the “TCP” 9600DFM conductor etch system, which are available from Lam Research Corporation, located in Freemont, Calif.

### EXAMPLES

Components made of quartz that had been exposed to a plasma environment in a plasma processing apparatus were cleaned by an embodiment of the methods of cleaning described above. Particularly, the components were subjected to enhanced wet cleaning including the following procedures. The components were rinsed using DI water for about 5 minutes, followed by blow drying. The components were then immersed in isopropyl alcohol at ambient temperature for about 20 minutes, and then wiped with a non-contaminating wipe until no visible residue was removed from the quartz surface(s) on the wipe. The components were then rinsed using DI water for about 10 minutes, after which the component was dried. The components were then immersed in acetone at ambient temperature for about 20 minutes, and then wiped with a non-contaminating wipe until no visible residue was removed from the quartz surface(s) on the wipe. The components were then rinsed using DI water for about 10 minutes followed by drying. Then, the components were ultrasonically cleaned in ultra-pure water for from about 30 minutes, followed by drying with filtered nitrogen.

Next, the components were immersed in a solution of ammonium hydroxide, hydrogen peroxide and water, having a volume ratio of 1:1:2, at ambient temperature for about 30 minutes. Then, the components were rinsed with DI water for about 10 minutes and blow dried with nitrogen.

Next, the components were immersed in an aqueous 6 wt % HCl solution at ambient temperature for about 10 minutes. Then, the components were rinsed with DI water and blow dried with nitrogen.

Next, the components were immersed for about 10 minutes in a mixed acid solution containing about 1 wt % hydrofluoric acid and about 10 wt % nitric acid at ambient temperature for about 10 minutes. The components were rinsed with DI water for about 10 minutes and blow dried with nitrogen. This procedure was repeated twice, so that the components were immersed in the mixed acid solution for a total of about 30 minutes.

The components were then subjected to final cleaning in a class 100 clean room. The components were fully immersed in ultra-pure DI water in a tank for about 10 minutes. Then, the components were ultrasonically cleaned in ultra-pure water for about 60 minutes. Then, the components were fully immersed into ultra-pure DI water in a tank for about 10 minutes. The components were next dried by heating at a temperature of about 120° C. for about 1 hour. Finally, the components were double packaged with class 100 packing bags.

The pre-clean and post-clean surface contamination levels of various metals on the quartz surfaces of the components were measured using an ICP-MS. The results are shown in the following Table. In Example 1, the following amounts of metallic contaminants were achieved (units: ×10¹⁰ atoms/cm²) on the quartz surfaces by the wet cleaning process (the preferred maximum levels of the respective elements are shown in parenthesis): Al: 300 (≦300); Ca: 19 (≦95); Cr: <5 (≦50); Cu: <2 (≦50); Fe: 17 (≦65); Li: <3 (≦50); Mg: <10 (≦50); Ni: 3.5 (≦50); K: <10 (≦100); Na: <10 (≦100); Ti: 11 (≦60), Zn: <3 (≦50), Co: <1 (≦30) and Mo: <0.3 (≦30). In Example 2, the following amounts of metallic contaminants were achieved on the quartz surfaces by the wet cleaning process: Al: 280 (≦300); Ca: 41 (≦95); Cr: <5 (≦50); Cu: <2 (≦50); Fe: 31 (≦65); Li: 15 (≦50); Mg: 37 (≦50); Ni: <2 (≦50); K: 12 (≦100); Na: 26 (≦100); Ti: 15 (≦50), Zn: 25 (≦50), Co: <1 (≦30) and Mo: <0.3 (≦30). In Example 3, the following amounts of metallic contaminants were achieved on the quartz surfaces by the wet cleaning process: Al: 280 (≦300); Ca: 43 (≦95); Cr: <5 (≦50); Cu: <2 (≦50); Fe: 16 (≦65); Li: 22 (≦50); Mg: 21 (≦50); Ni: <2 (≦50); K: 19 (≦100); Na: 56 (≦100); Ti: <5 (≦60), Zn: 3.1 (≦50), Co: <1 (≦30) and Mo: <0.3 (≦30). Accordingly, the test results demonstrate that the wet cleaning methods can be used to clean quartz surfaces of components for plasma processing apparatuses to achieve low amounts of metallic contaminants, including metallic contaminants that are detrimental in semiconductor devices.

TABLE
SURFACE METALLIC CONTAMINATION LEVEL (×10¹⁰ atoms/cm²)

| | Detection | | | | | | |
|---|---|---|---|---|---|---|---|
| | Limit of | Pre- | Post- | Pre- | Post- | Pre- | Post- |
| Metal | Metal | Clean 1 | Clean 1 | Clean 2 | Clean 2 | Clean 3 | Clean 3 |
| Aluminum | 10 | 66,000 | 300 | 38,000 | 280 | 3,700 | 300 |
| Antimony | 0.1 | 460 | <0.1 | 1.6 | <0.1 | 2.2 | <0.1 |
| Arsenic | 1 | 10 | <1 | <1 | <1 | <1 | <1 |
| Barium | 0.3 | 680 | <0.3 | 74 | <0.3 | 16 | 0.5 |
| Beryllium | 5 | <5 | <5 | 19 | <5 | <5 | <5 |
| Bismuth | 0.1 | 1.1 | <0.1 | 2.0 | <0.1 | 0.6 | <0.1 |
| Boron | 50 | 3,400 | <50 | 390 | 76 | 590 | 83 |
| Cadmium | 0.2 | 27 | <0.2 | 1.3 | <0.2 | 1.4 | <0.2 |
| Calcium | 10 | 54,000 | 19 | 44,000 | 41 | 9,900 | 43 |
| Chromium | 5 | 6,100 | <5 | 7.4 | <5 | 22 | <5 |
| Cobalt | 1 | 83 | <1 | 3.8 | <1 | 1.6 | <1 |
| Copper | 2 | 1,600 | <2 | 89 | <2 | 490 | <2 |
| Gallium | 0.2 | 12 | <0.2 | 0.7 | <0.2 | 0.3 | <0.2 |
| Germanium | 0.3 | 20 | 4.6 | 24 | 3.8 | 5.9 | 5 |
| Iron | 5 | 100,000 | 17 | 2,600 | 31 | 2,500 | 16 |
| Lead | 0.1 | 280 | <0.1 | 8.9 | <0.1 | 34 | 0.1 |
| Lithium | 3 | 78 | <3 | 87 | 15 | 86 | 22 |
| Magnesium | 10 | 8,300 | <10 | 20,000 | 37 | 3,700 | 21 |
| Manganese | 1 | 1,500 | <1 | 120 | <1 | 39 | <1 |
| Molybdenum | 0.3 | 670 | <0.3 | 0.85 | <0.3 | 0.8 | <0.3 |
| Nickel | 2 | 5,300 | 3.5 | 240 | <2 | 210 | <2 |
| Potassium | 10 | 12,000 | <10 | 36,000 | 12 | 2,400 | 19 |
| Sodium | 10 | 38,000 | <10 | 69,000 | 26 | 16,000 | 56 |
| Strontium | 0.3 | 230 | <0.3 | 190 | <0.3 | 35 | <0.3 |
| Tin | 1 | 540 | <1 | 5.6 | <1 | 2.9 | <1 |
| Titanium | 5 | 2,000 | 11 | 410 | 15 | 260 | <5 |
| Tungsten | 0.5 | 27 | <0.5 | 5.1 | <0.5 | <0.5 | <0.5 |
| Vanadium | 1 | 44 | <1 | 3.1 | <1 | 2.7 | <1 |
| Zinc | 3 | 160,000 | <3 | 4,700 | 25 | 2,900 | 3.1 |
| Zirconium | 0.1 | 59 | 3.1 | 99 | 5.5 | 17 | 4.5 |

The present invention has been described with reference to preferred embodiments. However, it will be readily apparent to those skilled in the art that it is possible to embody the invention in specific forms other than as described above without departing from the spirit of the invention. The preferred embodiments are illustrative and should not be considered restrictive in any way. The scope of the invention is given by the appended claims, rather than the preceding description, and all variations and equivalents which fall within the range of the claims are intended to be embraced therein.

What is claimed is:

1. A method for wet cleaning at least one quartz surface of a component for a plasma processing chamber in which semiconductor substrates are processed, the method comprising:
a) contacting the at least one quartz surface of the component with at least one organic solvent effective to degrease and remove organic contaminants from the quartz surface;
b) after a), contacting the quartz surface with a weak basic solution which is effective to remove organic and metallic contaminants from the quartz surface;
c) after b), contacting the quartz surface with a first acid solution which is effective to remove metallic contaminants from the quartz surface;
d) after c), contacting the quartz surface with a second acid solution comprising hydrofluoric acid and nitric acid to remove metal contaminants from the quartz surface; and
e) optionally repeating d) at least once.

2. The method of claim 1, wherein a) comprises:
contacting the quartz surface with isopropyl alcohol by wiping or immersion;
then rinsing the quartz surface;
then contacting the quartz surface with acetone by wiping or immersion; and
then ultrasonically cleaning the component in deionized water.

3. The method of claim 1, wherein the basic solution comprises ammonium hydroxide, hydrogen peroxide and water in a respective volume ratio of about 1:1:2-8 or 1:2-7:8.

4. The method of claim 1, wherein the first acid solution comprises hydrochloric acid.

5. The method of claim 1, wherein:
the second acid solution comprises from about 1 wt % to about 5 wt % hydrofluoric acid and from about 5 wt % to about 20 wt % nitric acid, or about 1 wt % of hydrofluoric acid and about 10 wt % of nitric acid;
d) comprises immersing the component in the second acid solution for from about 10 minutes to about 20 minutes; and
e) comprises repeating d) twice such that the component is immersed in the second acid solution for a total of from about 30 to about 60 minutes.

6. The method of claim 1, further comprising after e):
rinsing the component with ultra-pure water;
then ultrasonically cleaning the component with ultra-pure water;
then rinsing component with ultra-pure water;
then drying the component at an elevated temperature; and
then packaging the component.

7. The method of claim 1, further comprising, prior to a), pre-cleaning the component by:
spraying the component with high-pressure deionized water; and
drying the component.

8. The method of claim 1, wherein the amounts (units: ×10¹⁰ atoms/cm²) of the following elements on the as-cleaned quartz surface are: Al≦300; Ca≦95; Cr≦50; Cu≦50; Fe≦65; Li≦50; Mg≦50; Ni≦50; K≦100; Na≦100; Ti≦60, Zn≦50, Co≦30 and Mo≦30.

9. The method of claim 1, wherein the component is selected from the group consisting of a dielectric window, gas injector, view port, plasma confinement ring, focus ring, edge ring, gas distribution plate and baffle.

10. A component comprising at least one quartz surface that has been wet cleaned by the method according to claim 1.

11. A method for wet cleaning at least one quartz surface of a component for a plasma processing chamber in which semiconductor substrates are processed, the method comprising:
a) contacting the at least one quartz surface of the component with isopropyl alcohol and then with acetone to degrease and remove organic contaminants from the quartz surface;
b) after a), contacting the quartz surface with a solution comprising ammonium hydroxide and hydrogen peroxide to remove organic and metallic contaminants from the quartz surface;
c) after b), contacting the quartz surface with a first acid solution comprising hydrochloric acid to remove metallic contaminants from the quartz surface;
d) after c), contacting the quartz surface with a mixed second acid solution comprising hydrofluoric acid and nitric acid to remove metallic contaminants from the quartz surface; and
e) optionally repeating d) at least once.

12. The method of claim 11, wherein:
the second acid solution comprises from about 1 wt % to about 5 wt % hydrofluoric acid and from about 5 wt % to about 20 wt % nitric acid, or about 1 wt % of hydrofluoric acid and about 10 wt % of nitric acid;
d) comprises immersing the component in the second acid solution for from about 10 minutes to about 20 minutes; and
e) comprises repeating d) twice, wherein the component is immersed in the second acid solution for a total of from about 30 to about 60 minutes for the three immersions.

13. The method of claim 11, further comprising after e):
rinsing the component with ultrapure water;
then ultrasonically cleaning the component with ultrapure water;
then rinsing component with ultrapure water;
then drying the component at an elevated temperature; and
then packaging the component.

14. The method of claim 11, further comprising prior to a) pre-cleaning the component by:
spraying the component with high-pressure deionized water; and
then drying the component.

15. The method of claim 11, wherein the component is selected from the group consisting of a dielectric window, gas injector, view port, plasma confinement ring, focus ring, edge ring, gas distribution plate and baffle.

16. The method of claim 11, wherein the amounts (units: ×10¹⁰ atoms/cm²) of the following elements on the as-cleaned quartz surface are: (×10¹⁰ atoms/cm²): Al≦300; Ca≦95; Cr≦50; Cu≦50; Fe≦65; Li≦50; Mg≦50; Ni≦50; K≦100; Na≦100; Ti≦60, Zn≦50, Co≦30 and Mo≦30.

17. A component comprising at least one quartz surface that has been wet cleaned by the method according to claim 11.

18. A component for a plasma processing chamber in which semiconductor substrates are processed, the component comprising at least one quartz surface on which the amounts of Al, Ca, Cr, Cu, Fe, Li, Mg, Ni, K, Na, Ti, Zn, Co and Mo are as follows (×10¹⁰ atoms/cm²): Al≦300; Ca≦95; Cr≦50; Cu≦50; Fe≦65; Li≦50; Mg≦50; Ni≦50; K≦100; Na≦100; Ti≦60, Zn≦50, Co≦30 and Mo≦30.

19. The component of claim 18, wherein the component is a baffle for a resist stripping chamber, the baffle includes an inner portion and a peripheral portion, wherein the inner portion includes an opaque central projection and a plurality of concentric rows of the gas passages surrounding the central projection, the central projection includes an upper surface and a plurality of through passages oriented at an acute angle relative to the upper surface such that the through passages extend in radial outward directions toward the peripheral portion.

20. The component of claim 19, further comprising a liner adapted to be supported by a plurality of liner supports on an upper surface of the baffle adjacent to a cover of the resist stripping chamber such that a plenum is defined between a bottom surface of the liner and an upper surface of the baffle when the baffle is disposed in the resist stripping chamber, the plenum being in fluid communication with the remote plasma source and the resist stripping chamber.

21. The component of claim 18, wherein the component is selected from the group consisting of a dielectric window, gas injector, gas injection ring, view port, plasma confinement ring, focus ring, edge ring, gas distribution plate and baffle.

22. A resist stripping apparatus, comprising:
a resist stripping chamber;
a remote plasma source operable to generate a plasma and introduce reactive species into the resist stripping chamber; and
a baffle according to claim 19 disposed in the resist stripping chamber.

23. A plasma processing chamber comprising at least one component including at least one quartz surface that has been cleaned by the method according to claim 1, the quartz surface being exposed to plasma and/or process gases in the plasma processing chamber.

24. The plasma processing apparatus of claim 23, wherein the component is selected from the group consisting of a dielectric window, gas injector, view port, plasma confinement ring, focus ring, edge ring, gas distribution plate and baffle.

25. A method of processing a semiconductor substrate in a plasma processing chamber, comprising:
cleaning at least one component having at least one quartz surface by the method according to claim 1;
placing the at least one as-cleaned component in the plasma processing chamber such that the component is exposed to plasma and/or process gas, the plasma processing chamber containing a semiconductor substrate;
energizing a process gas into the plasma state remote from or inside the plasma processing chamber and processing the semiconductor substrate.
